(19) United States
(12) Patent Application Publication
(10) Pub. No.: US 2015/0240066 A1
(43) Pub. Date: Aug. 27, 2015

(54) POLYMER COMPOSITION, MOLDED PRODUCT THEREOF, AND BACKSHEET FOR SOLAR CELL

(71) Applicant: ASAHI GLASS COMPANY, LIMITED, Tokyo (JP)

(72) Inventors: Tomoaki NAKANISHI, Tokyo (JP); Seigo Kotera, Tokyo (JP); Toshiaki Sawada, Tokyo (JP)

(73) Assignee: ASAHI GLASS COMPANY, LIMITED, Tokyo (JP)

(21) Appl. No.: 14/707,019

(22) Filed: May 8, 2015

Related U.S. Application Data
(63) Continuation of application No. PCT/JP2013/084958, filed on Dec. 26, 2013.

(30) Foreign Application Priority Data
Dec. 27, 2012 (JP) 2012-286198

(51) Int. Cl. C08L 33/12; C08J 5/18; H01L 31/049; C08L 27/18

(52) U.S. Cl. CPC C08L 33/12; C08L 27/18; C08J 5/18; H01L 31/049; C08J 2327/18; C08J 2333/12; C08J 2433/12; C08J 2427/18; C08L 2201/02; C08L 2203/16; C08L 2203/204; C08L 2205/025; C08L 2205/03

(57) ABSTRACT

To provide a polymer composition containing an ethylene/tetrafluoroethylene copolymer, which is excellent in elongation, a molded product thereof, a film and a backsheet for a solar cell. A polymer composition comprising an ethylene/tetrafluoroethylene copolymer, a poly(meth)acrylate and a fluoroelastomer; a molded product made of such a composition; a method for producing such a molded product; and a backsheet for a solar cell, which contains a film made of the polymer composition.

### TECHNICAL FIELD

The present invention relates to a polymer composition containing an ethylene/tetrafluoroethylene copolymer, a molded product thereof, and a backsheet for a solar cell.

### BACKGROUND ART

Fluororesins are excellent in solvent resistance, low-dielectric constant, low surface energy properties, non-adhesive properties, weather resistance, etc. and thus are used in various applications where general-purpose plastics cannot be used. Among them, an ethylene/tetrafluoroethylene copolymer (hereinafter referred to also as “ETFE”) is a fluororesin excellent in heat resistance, flame resistance, chemical resistance, weather resistance, low frictional properties, low dielectric constant, etc. and thus is used in a wide range of fields including e.g. a coating material for heat-resistant electric wires, a corrosion resistant piping material for chemical plants, a material for agricultural plastic green houses, a mold release film, etc. With a view to e.g. improving the melt processability, it has heretofore been attempted to blend to ETFE another melt-moldable resin (e.g. Patent Document 1).

Further, it has been proposed to blend a fluororesin to a melt-moldable polymer composition containing no fluorine atoms to improve the melt-moldable polymer composition (e.g. Patent Document 2).

### PRIOR ART DOCUMENTS

### Patent Documents

Patent Document 1: JP-A-60-72951

Patent Document 2: JP-A-2002-544359

### DISCLOSURE OF INVENTION

### Technical Problem

However, the blend disclosed in Patent Document 1 had a problem such that since ETFE is in general immiscible with another resin, the immiscible dispersed phase was likely to be coarsening, thereby to deteriorate elongation, etc.

Whereas, the melt-moldable resin disclosed in the Patent Document 2 was not necessarily able to provide sufficient effects for improvement, since the melt-moldable resin containing no fluorine atoms and the fluororesin are immiscible.

It is an object of the present invention to provide a polymer composition containing an ethylene/tetrafluoroethylene copolymer, which is excellent in elongation, a molded product thereof, a film and a backsheet for a solar cell.

### Solution to Problem

The present invention provides a polymer composition containing an ethylene/tetrafluoroethylene copolymer, a molded product made of such a composition, a method for producing such a molded product, and a backsheet for a solar cell, containing a film made of the polymer composition, having the following constructions [1] to [15].

[1] A polymer composition comprising an ethylene/tetrafluoroethylene copolymer, a poly(meth)acrylate and a fluoroelastomer.
[2] The polymer composition according to [1], wherein the mass ratio of the ethylene/tetrafluoroethylene copolymer to the poly(meth)acrylate, is from 10:90 to 99.9:0.1, and the content of the fluoroelastomer is from 1 to 30% in the total mass of the ethylene/tetrafluoroethylene copolymer, the poly(meth)acrylate and the fluoroelastomer.
[3] The polymer composition according to [1] or [2], wherein the poly(meth)acrylate is a polymethyl methacrylate.
[4] The polymer composition according to any one of [1] to [3], wherein the fluoroelastomer is a tetrafluoroethylene/propylene copolymer or a tetrafluoroethylene/propylene/vinylidene fluoride copolymer.
[5] The polymer composition according to any one of [1] to [4], having the ethylene/tetrafluoroethylene copolymer, the poly(meth)acrylate and the fluoroelastomer melt-kneaded.
[6] The polymer composition according to [5], wherein the poly(meth)acrylate is a polymethyl methacrylate, and the mass ratio of the ethylene/tetrafluoroethylene copolymer to the polymethyl methacrylate is from 50:50 to 80:20.
[7] The polymer composition according to [6], wherein the polymer composition has a microphase-separated structure wherein the continuous phase is the ethylene/tetrafluoroethylene copolymer, and the dispersed phase is the polymethyl methacrylate.
[8] The polymer composition according to [5], wherein the poly(meth)acrylate is a polymethyl methacrylate, and the mass ratio of the ethylene/tetrafluoroethylene copolymer to the polymethyl methacrylate is from 10:90 to 49:51.
[9] The polymer composition according to [8], wherein the polymer composition has a microphase-separated structure wherein the dispersed phase is the ethylene/tetrafluoroethylene copolymer, and the continuous phase is the polymethyl methacrylate.
[10] A molded product obtained by melt-molding the polymer composition as defined in any one of [1] to [9].
[11] The molded product according to [10], wherein the poly(meth)acrylate is a polymethyl methacrylate.
[12] The molded product according to [11], wherein the polymer composition has a microphase-separated structure having a continuous phase and a dispersed phase, wherein either one of the ethylene/tetrafluoroethylene copolymer and the polymethyl methacrylate constitutes the continuous phase, and the other constitutes the dispersed phase.
[13] The molded product according to any one of [10] to [12], wherein the molded product is a film or sheet.
[14] A backsheet for a solar cell, which contains a layer of the film as defined in [13] having a thickness of from 10 to 100 μm.
[15] A method for producing a molded product, which comprises melt-molding a polymer composition comprising an ethylene/tetrafluoroethylene copolymer, a poly(meth)acrylate and a fluoroelastomer.

### Advantageous Effects of Invention

The polymer composition of the present invention provides a molded product excellent in elongation deformation.

Further, the molded product of the present invention is excellent in elongation deformation and excellent in heat resistance.

### BRIEF DESCRIPTION OF DRAWINGS

FIG. 1 is a view showing a cross-sectional surface backscattered electron image (magnification: 500 times) of a strand of a molded product of the polymer composition in Example 1.

FIG. 2 is a view showing a cross-sectional surface backscattered electron image (magnification: 500 times) of a strand of a molded product of the polymer composition in Comparative Example 1.

FIG. 3 is a view showing a cross-sectional surface backscattered electron image (magnification: 1,000 times) of a strand of a molded product of the polymer composition in Example 7.

FIG. 4 is a view showing a cross-sectional surface backscattered electron image (magnification: 1,000 times) of a strand of a molded product of the polymer composition in Comparative Example 4.

### DESCRIPTION OF EMBODIMENTS

In the present invention, a “poly(meth)acrylate” is a general term for a polymethacrylate and a polyacrylate. Further, hereinafter, an ethylene/tetrafluoroethylene copolymer will be referred to also as ETFE.

The polymer composition of the present invention comprises ETFE, a poly(meth)acrylate and a fluoroelastomer.

### (ETFE)

In the present invention, ETFE is a polymer which has constituent units based on tetrafluoroethylene (hereinafter referred to as “TFE”) and constituent units based on ethylene. The molar ratio of constituent units based on TFE/constituent units based on ethylene in ETFE is preferably from 20/80 to 80/20, more preferably from 30/70 to 70/30, most preferably from 40/60 to 60/40.

ETFE may contain constituent units based on another monomer in addition to constituent units based on TFE and ethylene. Such another monomer may, for example, be a fluoroethylene (excluding TFE) such as CF₂═CFCl or CF₂═CH₂; a C₃₋₅ perfluoro-olefin such as hexafluoropropylene (hereinafter referred to as HFP) or octafluorobutene-1; a polyfluoroalkylethylene represented by X¹(CF₂)ₙCY═CH₂ (wherein each of X¹ and Y is a hydrogen atom or a fluorine atom, and n is an integer of from 2 to 8); a perfluorovinylether such as (R^{f}OCFX²CF₂)ₙOCF═CF₂ (wherein R^{f} is a C₁₋₆ perfluoroalkyl group, X² is a fluorine atom or a trifluoromethyl group, and n is an integer of from 0 to 5); a perfluorovinylether having a group readily convertible to a carboxylic group or sulfo group, such as CH₃OC(═O)CF₂CF₂CF₂OCF═CF₂ or FSO₂CF₂CF₂OCF(CF₃)CF₂OCF═CF₂; a perfluorovinylether having an unsaturated bond, such as CF₂═CFOCF₂CF═CF₂ or CF₂═CFO(CF₂)₂CF═CF₂; a fluorinated monomer having an alicyclic structure, such as perfluoro(2,2-dimethyl-1,3-dioxole), 2,2,4-trifluoro-5-trifluoromethoxy-1,3-dioxole or perfluoro(2-methylene-4-methyl-1,3-dioxolane); or an olefin (excluding ethylene) such as a C₃ olefin such as propylene, or a C₄ olefin such as butylene or isobutylene.

In the above polyfluoroalkylethylene represented by X¹(CF₂)ₙCY═CH₂, n is preferably from 2 to 6, more preferably from 2 to 4. Its specific examples may, for example, be CF₃CF₂CH═CH₂, CF₃(CF₂)₃CH═CH₂, CF₃(CF₂)₅CH═CH₂, CF₃CF₂CF₂CF═CH₂, CF₂HCF₂CF₂CF═CH₂, CF₂HCF₂CF₂CF═CH₂, etc.

Further, specific examples of the above perfluorovinylether may, for example, be perfluoro(methyl vinyl ether), perfluoro(ethyl vinyl ether), perfluoro(propyl vinyl ether) (hereinafter referred to as “PPVE”), CF₂═CFOCF₂CF(CF₃)O(CF₂)₂CF₃, CF₂═CFO(CF₂)₃O(CF₂)₂CF₃, CF₂═CFO(CF₂CF(CF₃)O)₂(CF₂)₂CF₃, CF₂═CFOCF₂CF₂OCF₂CF₃ and CF₂═CFO(CF₂CF₂O)₂CF₂CF₃.

Another monomer is preferably the above polyfluoroalkylethylene, the perfluoro-olefin (other than TFE) such as HFP, or the perfluorovinylether such as PPVE, more preferably HFP, PPVE, CF₃CF₂CH═CH₂ or CF₃(CF₂)₃CH═CH₂. Further, as such another monomer, one type may be used alone, or two or more types may be used in combination.

The proportion of constituent units based on such another monomer is preferably from 0.1 to 10 mol %, more preferably from 0.2 to 6 mol %, most preferably from 0.5 to 3 mol %, in all constituent units (100 mol %) in ETFE.

The melt viscosity of ETFE in the present invention is preferably from 50 to 400 Pa·s at a measuring temperature of 270° C. Commercial products of ETFE may, for example, be Aflon ETFE-C88AXMB (manufactured by Asahi Glass Company, Limited) and Aflon ETFE-LM740AP (manufactured by Asahi Glass Company, Limited).

### (Poly(Meth)Acrylate)

The poly(meth)acrylate in the present invention is preferably an alkyl methacrylate or alkyl acrylate having an alkyl group with at most 4 carbon atoms. Particularly preferred is a polymethyl methacrylate (hereinafter referred to also as “PMMA”).

The melt viscosity of PMMA in the present invention is preferably from 50 to 400 Pa·s at a measuring temperature of 270° C. Commercial products of PMMA may, for example, be ACRYPET VH3 (manufactured by Mitsubishi Plastics, Inc.) and VH4 (manufactured by Mitsubishi Plastics, Inc.).

### (Fluoroelastomer)

In the present invention, specific examples of the fluoroelastomer may, for example, be a vinylidene fluoride/hexafluoropropylene copolymer, a vinylidene fluoride/tetrafluoroethylene/hexafluoropropylene copolymer, a vinylidene fluoride/chlorotrifluoroethylene copolymer, a tetrafluoroethylene/propylene copolymer, a tetrafluoroethylene/propylene/vinylidene fluoride copolymer, a tetrafluoroethylene/propylene/vinyl fluoride copolymer, a tetrafluoroethylene/propylene/trifluoroethylene copolymer, a tetrafluoroethylene/propylene/pentafluoropropylene copolymer, a tetrafluoroethylene/propylene/chlorotrifluoroethylene copolymer, a tetrafluoroethylene/propylene/ethylidene norbornene copolymer, a hexafluoropropylene/ethylene copolymer, a tetrafluoroethylene/perfluoro(alkyl vinyl ether) copolymer, a vinylidene fluoride/tetrafluoroethylene/perfluoro(alkyl vinyl ether) copolymer, etc.

As the fluoroelastomer, preferred is a tetrafluoroethylene/propylene copolymer (hereinafter referred to also as a “TFE/P copolymer”) or a tetrafluoroethylene/propylene/vinylidene fluoride copolymer (hereinafter referred to also as a “TFE/P/VdF copolymer”).

In the above TFE/P copolymer, the molar ratio of constituent units based on TFE/constituent units based on propylene is preferably from 40/60 to 70/30, more preferably from 45/55 to 65/35, most preferably from 50/50 to 60/40.

Further, in the TFE/P/VdF copolymer, the molar ratio of constituent units based on TFE/constituent units based on propylene/constituent units based on vinylidene fluoride is preferably from 50/5/45 to 65/30/5, more preferably from 50/15/35 to 65/25/10, most preferably from 50/20/30 to 65/20/15.

A commercial product of the TFE/P copolymer may, for example, be AFLAS 150C (manufactured by Asahi Glass Company, Limited). A commercial product of the TFE/P/VdF copolymer may, for example, be AFLAS 200P (manufactured by Asahi Glass Company, Limited).

### (Polymer Composition)

The polymer composition of the present invention comprises the above ETFE, poly(meth)acrylate and fluoroelastomer. In the polymer composition, the mass ratio of ETFE to the poly(meth)acrylate is preferably from 10:90 to 99.9:0.1, more preferably from 10:90 to 95:5, further preferably from 20:80 to 90:10, most preferably from 50:50 to 80:20.

Further, as the case requires, the polymer composition of the present invention may contain a stabilizer such as an ultraviolet absorber, or an additive such as a light-shielding pigment or a powder filler.

Particularly when the poly(meth)acrylate is PMMA, and the mass ratio of ETFE to PMMA is within a range of from 50:50 to 80:20, the polymer composition having ETFE, PMMA and the fluoroelastomer melt-kneaded and cooled, tends to readily form a morphology of a microphase-separated structure wherein the continuous phase is ETFE, and the dispersed phase is PMMA. Further, when the mass ratio of ETFE to PMMA is from 10:90 to 49:51, the polymer composition tends to readily form a morphology of a microphase-separated structure wherein the dispersed phase is ETFE, and the continuous phase is PMMA.

It is reported that formation of a morphology of a microphase-separated structure in a composition having two types of resins blended, is empirically predictable from the volume ratio and melt viscosity ratio of the respective resins (G. M. Jordhamo, J. A. Manson and L. H. Sperling, Polym. Eng. Sci., 26, 517 (1986)).

The content of the fluoroelastomer in the polymer composition of the present invention is preferably from 1 to 30%, more preferably from 1 to 10%, most preferably from 2 to 5%, in the total mass of the polymer composition. Within this range, the dispersibility of the above dispersed phase is improved, so that microsizing be facilitated. As a result, a molded product obtained by using such a polymer composition will be excellent in elongation.

The polymer composition of the present invention is preferably one produced by melt-kneading ETFE, PMMA and the fluoro-resin. A microphase-separated structure of a polymer composition is usually such that the microphase-separated structure appears in a solid state melt-kneaded product, and a molten state melt-kneaded product has a uniform structure.

The molten state melt-kneaded product may be produced by such a method that a mixture of the above polymers is kneaded while being melted, or the above polymers are mixed and kneaded while being melted, and the solid state melt-kneaded product may be formed by cooling the molten state melt-kneaded mixture. Further, the molten state melt-kneaded product may be continuously subjected to molding. Further, the cooled melt-kneaded product may be used as a molding material for e.g. melt-molding to produce a molded product of the polymer composition.

The melt-kneading temperature is preferably from 260 to 300° C., most preferably from 270 to 280° C. The melt-kneading time is preferably from 5 to 20 minutes.

### (Molded Product)

The molded product of the present invention is prepared by molding the polymer composition. As the molding method, melt-molding is preferred. In the melt-molding, ETFE, PMMA and the fluoroelastomer are melt-kneaded, followed by molding. Otherwise, melt-molding may be made by using, as a molding material, a solid state melt-kneaded product having preliminarily melt-kneaded and cooled. Further, a molding material in a pellet or massive form may preliminarily be produced by melt-molding, and then, such a molding material is subjected to melt-molding. The melt-molding is preferably extrusion molding or inflation molding to produce a continuous molded product such as a film or sheet, or injection molding or press molding by means of a mold, die, etc.

In the melt-molding such as extrusion molding or injection molding, a molding material is melted and molded. At the time of such melting, it is common to knead the molding material while melting it. Accordingly, ETFE, PMMA and a fluoroelastomer can be mixed and melt-kneaded in a melt-molding device, and therefore, a molding material made of ETFE, a molding material made of PMMA and a molding material made of a fluoroelastomer may be introduced into the melt-molding device without preliminarily melt-kneading them, so that the melt-kneading is conducted in the melt-molding device, followed by molding to produce a molded product made of the polymer composition.

Further, the temperature condition in the melt-molding is preferably from 240 to 300° C., more preferably from 240 to 280° C., most preferably from 250 to 270° C. The molding time in the melt-molding is preferably from 1 to 30 minutes, more preferably from 1 to 20 minutes, most preferably from 1 to 15 minutes.

The molded product made of the polymer composition is preferably a film or sheet. In the present invention, the film or sheet is meant for a molded product having substantially a constant thickness. The film is meant for one having a thickness of at most 0.2 mm, and the sheet is meant for one having a thickness exceeding 0.2 mm. However, a film or sheet in a commonly employed name such as a backsheet for a solar cell, is not necessarily limited to the above mentioned thickness.

The thickness of the film or sheet of the present invention is preferably from 1 to 800 μm, more preferably from 5 to 500 μm.

The film or sheet is suitable for use, for example, as a film for agriculture or a backsheet for a solar cell, which is required to have weather resistance. When it is to be used for a backsheet for a solar cell, the film of the present invention preferably has a thickness of from 10 to 100 μm. Within this range, the film is available at a low cost and excellent in mechanical strength, weather resistance, light-shielding properties (easy blending of a light-shielding pigment), etc. which are required for e.g. a backsheet for a solar cell.

The molding method for a film or sheet may, for example, be extrusion molding, inflation molding, injection molding or press molding, but extrusion molding or press molding is preferred. The conditions for molding a film or sheet are preferably the same as the molding conditions (the molding temperature and molding time) for a molded product.

### EXAMPLES

Now, the present invention will be described with reference to Examples, but it should be understood that the present invention is by no means limited to these Examples.

The materials, processing and measuring methods used in Examples and Comparative Examples are as follows.

### [Materials]

ETFE1: Aflon ETFE-C88AXMB MFR169 manufactured by Asahi Glass Company, Limited, melt viscosity: 260 Pa·s (270° C.)

ETFE2: Aflon ETFE-LM740AP, melt viscosity: 510 Pa·s (270° C.)

ETFE3: Aflon ETFE-C88AXM, melt viscosity: 420 Pa·s (280° C.)

PMMA1: ACRYPET VH4 manufactured by Mitsubishi Plastics, Inc., melt viscosity: 350 Pa·s (270° C.)

PMMA2: ACRYPET VH3 manufactured by Mitsubishi Plastics, Inc., melt viscosity: 280 Pa·s (270° C.)

Fluoroelastomer 1: TFE/P copolymer, AFLAS-200S (manufactured by Asahi Glass Company, Limited), Mooney viscosity (ML1+10 100° C.) 51

Fluoroelastomer 2: TFE/P copolymer, AFLAS-150CS (manufactured by Asahi Glass Company, Limited), Mooney viscosity (ML1+10 100° C.) 140

### [Kneading]

Into a mixer (Laboplastomill manufactured by Toyo Seiki Seisaku-sho Ltd.) set at from 270 to 280° C., the materials shown in each Example or Comparative Example were put and preliminarily kneaded for 1 minute at a rotational speed of 20 rpm, followed by melt-kneading for 10 minutes at a rotational speed of 50 rpm to obtain a polymer composition.

### [Press Film Molding]

In a SUS316 mold having a thickness of 100 μm and a size of 100 mm square, the above polymer composition was filled and set in a press machine (Mini Test Press MP-WCL manufactured by Toyo Seiki Seisaku-sho Ltd.) set at from 270 to 280° C., and by using a SUS316 mirror-smooth polished plate of 150 mm×150 mm as a cover, after preheating for 5 minutes, compression molding was conducted at 8.7 MPa as the pressure for 5 minutes, followed by cooling with keeping the pressure of 8.7 MPa for 5 minutes, to obtain a film molded in the size of the mold and having a thickness of 100 μm.

### [Electron Microscopic Observation]

A polymer composition after melt-kneading obtained e.g. in Example 1 was preliminarily heated for 10 minutes by a capirograph (CAPIROGRAPH 1C manufactured by Toyo Seiki Seisaku-sho Ltd.) and extruded from a die with L/D=10 and a diameter of 1 mm at a speed of 50 mm/min. to prepare a strand. The obtained strand was cooled in liquid nitrogen and cut by a razor to prepare a sample, which was carbon-coated and subjected to photographing a backscattered electron image of the cross-section by a scanning electron microscope (S4300 manufactured by Hitachi, Ltd.) at an accelerated voltage of 5 kV.

### [Measurement of Properties]

In accordance with ASTM D1822-L, dumbbells were punched out from a film by means of a super dumbbell cutter (SDMK-100L manufactured by Dumbbell Co., Ltd.) and subjected to a tensile test at a speed of 10 mm/min. by means of a Tensilon universal tester (manufactured by A&D Company, Limited) to obtain the elastic modulus (MPa) and tensile elongation (%) with N number (number of specimens)=3 to 5.

### Example 1

As materials, 8.3 g of ETFE1, 5.7 g of PMMA1 and 0.8 g of fluoroelastomer 1 were kneaded at 270° C. by means of the above Laboplastomill mixer to obtain a polymer composition 1. The physical properties of a film obtained from the polymer composition 1 are shown in Table 1. Here, the numerical values in a row for each material are mass ratios. Further, the obtained electron microscopic image (magnification: 500 times) is shown in FIG. 1. In FIG. 1, the bright portion is the continuous phase of ETFE, and the dark portion is the dispersed phase of PMMA.

### Comparative Example 1

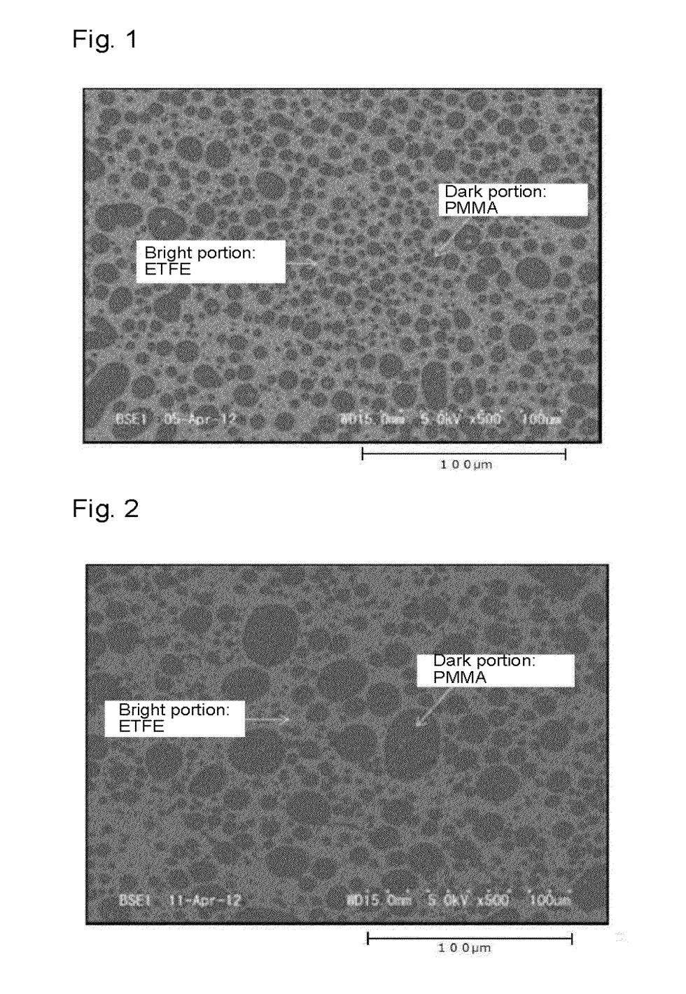

A polymer composition 2 was obtained in the same manner as in Example 1 except that as materials, fluoroelastomer 1 was not used, and 8.8 g of ETFE1 and 6.0 g of PMMA1 were used. The physical properties of a film obtained from the polymer composition 2 are shown in Table 1. Further, the obtained electron microscopic image (magnification: 500 times) is shown in FIG. 2. Also in FIG. 2, the bright portion is the continuous phase of ETFE, and the dark portion is the dispersed phase of PMMA.

### Example 2

A polymer composition 3 was obtained in the same manner as in Example 1 except that as materials, 11.0 g of ETFE2 and 3.2 g of PMMA2 and 1.7 g of fluoroelastomer 1 were used. The physical properties of a film obtained from the polymer composition 3 are shown in Table 1.

### Example 3

A polymer composition 4 was obtained in the same manner as in Example 1 except that as materials, 11.6 g of ETFE2 and 3.4 g of PMMA2 and 0.8 g of fluoroelastomer 1 were used. The physical properties of a film obtained from the polymer composition 4 are shown in Table 1.

### Example 4

A polymer composition 5 was obtained in the same manner as in Example 1 except that as materials, 12.0 g of ETFE2 and 3.5 g of PMMA2 and 0.3 g of fluoroelastomer 1 were used. The physical properties of a film obtained from the polymer composition 5 are shown in Table 1.

### Example 5

A polymer composition 6 was obtained in the same manner as in Example 1 except that as materials, 11.6 g of ETFE2 and 3.4 g of PMMA2 and 0.8 g of fluoroelastomer 2 were used. The physical properties of a film obtained from the polymer composition 6 are shown in Table 1.

### Comparative Example 2

A polymer composition 7 was obtained in the same manner as in Example 1 except that as materials, fluoroelastomer 1 was not used, and 12.3 g of ETFE2 and 3.6 g of PMMA2 were used. The physical properties of a film obtained from the polymer composition 7 are shown in Table 1.

### Example 6

A polymer composition 8 was obtained in the same manner as in Example 1 except that the temperature set for the Laboplastmill mixer was changed to 280° C. and as materials, 11.6 g of ETFE3 and 3.4 g of PMMA2 and 0.8 g of fluoroelastomer 2 were used. The physical properties of a film obtained from the polymer composition 8 are shown in Table 1.

### Comparative Example 3

A polymer composition 9 was obtained in the same manner as in Example 6 except that as materials, fluoroelastomer 2 was not used, and 12.3 g of ETFE3 and 3.6 g of PMMA2 were used. The physical properties of a film obtained from the polymer composition 9 are shown in Table 1.

### Example 7

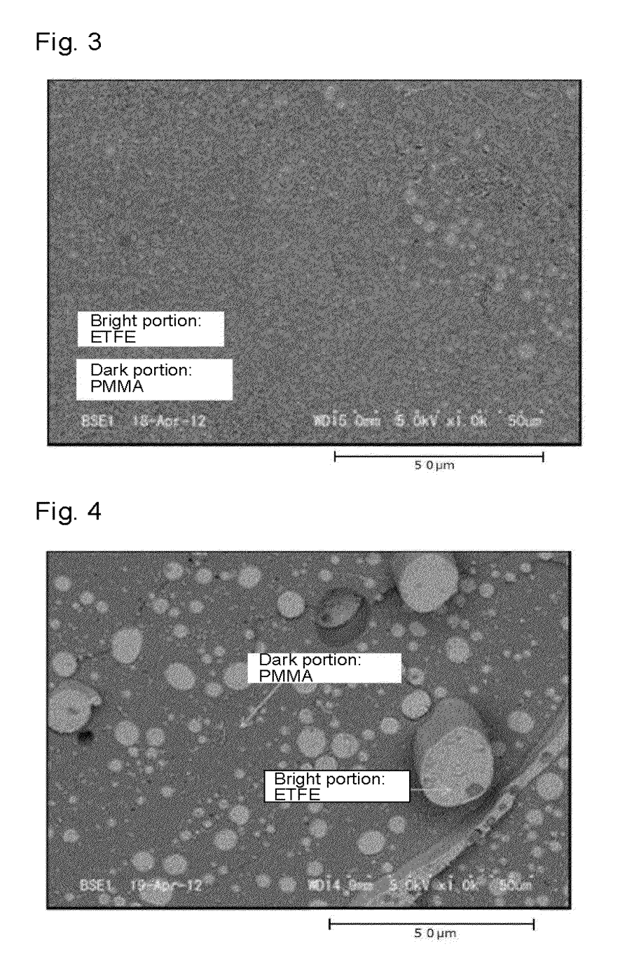

A polymer composition 10 was obtained in the same manner as in Example 1 except that as materials, 1.8 g of ETFE1 and 8.3 g of PMMA1 and 3.3 g of fluoroelastomer 1 were used. The physical properties of a film obtained from the polymer composition 10 are shown in Table 1. Further, the obtained electron microscopic image (magnification: 1,000 times) is shown in FIG. 3. In FIG. 3, the bright portion is the dispersed phase of ETFE, and the dark portion is the continuous phase of PMMA.

### Comparative Example 4

A polymer composition 11 was obtained in the same manner as in Example 1 except that as materials, fluoroelastomer 1 was not used, and 5.3 g of ETFE1 and 8.3 g of PMMA1 were used. The physical properties of a film obtained from the polymer composition 11 are shown in Table 1. Further, the obtained electron microscopic image (magnification: 1,000 times) is shown in FIG. 4. Also in FIG. 4, the bright portion is the dispersed phase of ETFE, and the dark portion is the continuous phase of PMMA.

TABLE 1

| | | | Comp. | | | | | Comp. | | Comp. | | Comp. |
|---|---|---|---|---|---|---|---|---|---|---|---|---|
| | | Ex. 1 | Ex. 1 | Ex. 2 | Ex. 3 | Ex. 4 | Ex. 5 | Ex. 2 | Ex. 6 | Ex. 3 | Ex. 7 | Ex. 4 |
| Materials | Composition | Pc 1 | Pc 2 | Pc 3 | Pc 4 | Pc 5 | Pc 6 | Pc 7 | Pc 8 | Pc 9 | Pc 10 | Pc 11 |
| | (mass ratio) | | | | | | | | | | | |
| | ETFE1 | 59 | 59 | — | — | — | — | — | — | — | 18 | 39 |
| | ETFE2 | — | — | 77 | 77 | 77 | 77 | 77 | — | — | — | — |
| | ETFE3 | — | — | — | — | — | — | — | 77 | 77 | — | — |
| | PMMA1 | 41 | 41 | — | — | — | — | — | — | — | 82 | 61 |
| | PMMA2 | — | — | 23 | 23 | 23 | 23 | 23 | 23 | 23 | — | — |
| | Fluoroelastomer | 5.7 | — | 12 | 5.3 | 1.9 | — | — | 5.3 | — | 32.7 | — |
| | 1 | | | | | | | | | | | |
| | Fluoroelastomer | — | — | — | — | — | 5.3 | — | — | — | — | — |
| | 2 | | | | | | | | | | | |
| Kneading | Temperature | 270 | 270 | 270 | 270 | 270 | 270 | 270 | 280 | 280 | 270 | 270 |
| | (° C.) | | | | | | | | | | | |
| Physical | Elastic modulus | 590 | 760 | 190 | 340 | 350 | 410 | 480 | 340 | 550 | 750 | 1100 |
| properties | (MPa) | | | | | | | | | | | |
| of film | Tensile | 12 | 2.8 | 380 | 320 | 310 | 290 | 270 | 220 | 180 | 19 | 1.6 |
| | elongation (%) | | | | | | | | | | | |

Pc: Polymer composition

In Table 1, from a comparison of Example 1 and Comparative Example 1, it is evident that the tensile elongation of the film is remarkably large when the polymer composition contains fluoroelastomer 1. Further, from a comparison of FIG. 1 (Example 1) and FIG. 2 (Comparative Example 1), it is evident that in FIG. 1, PMMA being the dispersed phase is microsized. This is considered to be due to that microsizing of PMMA is promoted by the interfacial activity of the fluoroelastomer. Further, the improvement in the tensile elongation is considered to be attributable to an effect of microsizing of PMMA by the addition of fluoroelastomer 1.

Likewise, from a comparison of Examples 2 to 5 and Comparative Example 2, the tensile elongation of the film is large when the polymer composition contains fluoroelastomer 1 or fluoroelastomer 2. Further, also from a comparison of Example 6 and Comparative Example 3, the same tendency is observed when the polymer composition contains the fluoroelastomer.

Further, in Example 7 and Comparative Example 4, as shown in FIGS. 3 and 4, respectively, in the polymer composition, ETFE is the dispersed phase, and PMMA is the continuous phase. Also in such a case, it is evident that as the composition contains the fluoroelastomer 1, the tensile elongation of the film in Example 7 is larger than in Comparative Example 4. Further, it is evident that ETFE as the dispersed phase is more finely microsized in Example 7 (FIG. 3) than in Comparative Example 4 (FIG. 4). Microsizing of ETFE is considered to be attributable to the interfacial activity of the fluoroelastomer, and the improvement in the tensile elongation is considered to be attributable to an effect of microsizing of the dispersed phase.

### INDUSTRIAL APPLICABILITY

The molded product of the present invention has, as mechanical heat resistance, a performance equal to PMMA while having an excellent surface state of ETFE and thus is useful as a molded member of resin type where a PMMA type material is used. Since it has a surface state of ETFE, it is expected to provide high weather resistance and is suitable for exterior use. Specifically, it is useful e.g. as a resin building material such as gutters, a molded product for signs or markers, or an exterior equipment of an automobile. Further, it may be molded into a film or sheet and thus is useful not only for a backsheet for a solar cell but also for a release film or a highly weather resistant sheet.

This application is a continuation of PCT Application No. PCT/JP2013/084958 filed Dec. 26, 2013, which is based upon and claims the benefit of priority from Japanese Patent Application No. 2012-286198 filed on Dec. 27, 2012. The contents of those applications are incorporated herein by reference in their entireties.

What is claimed is:

1. A polymer composition comprising an ethylene/tetrafluoroethylene copolymer, a poly(meth)acrylate and a fluoroelastomer.

2. The polymer composition according to claim 1, wherein the mass ratio of the ethylene/tetrafluoroethylene copolymer to the poly(meth)acrylate, is from 10:90 to 99.9:0.1, and the content of the fluoroelastomer is from 1 to 30% in the total mass of the ethylene/tetrafluoroethylene copolymer, the poly(meth)acrylate and the fluoroelastomer.

3. The polymer composition according to claim 1, wherein the poly(meth)acrylate is a polymethyl methacrylate.

4. The polymer composition according to claim 1, wherein the fluoroelastomer is a tetrafluoroethylene/propylene copolymer or a tetrafluoroethylene/propylene/vinylidene fluoride copolymer.

5. The polymer composition according to claim 1, having the ethylene/tetrafluoroethylene copolymer, the poly(meth)acrylate and the fluoroelastomer melt-kneaded.

6. The polymer composition according to claim 5, wherein the poly(meth)acrylate is a polymethyl methacrylate, and the mass ratio of the ethylene/tetrafluoroethylene copolymer to the polymethyl methacrylate is from 50:50 to 80:20.

7. The polymer composition according to claim 6, wherein the polymer composition has a microphase-separated structure wherein the continuous phase is the ethylene/tetrafluoroethylene copolymer, and the dispersed phase is the polymethyl methacrylate.

8. The polymer composition according to claim 5, wherein the poly(meth)acrylate is a polymethyl methacrylate, and the mass ratio of the ethylene/tetrafluoroethylene copolymer to the polymethyl methacrylate is from 10:90 to 49:51.

9. The polymer composition according to claim 8, wherein the polymer composition has a microphase-separated structure wherein the dispersed phase is the ethylene/tetrafluoroethylene copolymer, and the continuous phase is the polymethyl methacrylate.

10. A molded product obtained by melt-molding the polymer composition as defined in claim 1.

11. The molded product according to claim 10, wherein the poly(meth)acrylate is a polymethyl methacrylate.

12. The molded product according to claim 11, wherein the polymer composition has a microphase-separated structure having a continuous phase and a dispersed phase, wherein either one of the ethylene/tetrafluoroethylene copolymer and the polymethyl methacrylate constitutes the continuous phase, and the other constitutes the dispersed phase.

13. The molded product according to claim 10, wherein the molded product is a film or sheet.

14. A backsheet for a solar cell, which contains a layer of the film as defined in claim 13 having a thickness of from 10 to 100 μm.

15. A method for producing a molded product, which comprises melt-molding a polymer composition comprising an ethylene/tetrafluoroethylene copolymer, a poly(meth)acrylate and a fluoroelastomer.
